(19) United States
(12) Patent Application Publication
(10) Pub. No.: US 2019/0202124 A1
(43) Pub. Date: Jul. 4, 2019

(54) 3D PRINTER WITH COOLING FUNCTION

(71) Applicant: SINDOH CO., LTD., Seoul (KR)

(72) Inventors: Byoung-bag LEE, Seoul (KR); Ji-sung PARK, Seoul (KR); Seung-won HAN, Seoul (KR)

(21) Appl. No.: 16/238,580

(22) Filed: Jan. 3, 2019

(30) Foreign Application Priority Data
Jan. 4, 2018 (KR) 10-2018-0001066

(51) Int. Cl. B29C 64/268; H01S 5/00; H01S 5/024; B33Y 30/00; B33Y 50/02; B29C 64/393

(52) U.S. Cl. CPC B29C 64/268; H01S 5/0071; H01S 5/02407; B29C 64/393; H01S 5/02469; B33Y 30/00; B33Y 50/02; H01S 5/02415

(57) ABSTRACT

The present disclosure relates to a 3D printer having a cooling function, The 3D printer includes: a tank configured to store therein a photocurable liquid resin; a bed configured to support a shaping object; a bed transfer unit configured to move the bed in a vertical direction; a light projection unit configured to linearly project laser light to the photocurable liquid resin stored in the tank so as to cure the photocurable liquid resin into a shaping object; a light projection unit transfer unit configured to move the light projection unit; a control unit configured to control operations of the light projection unit, the light projection unit transfer unit, and the bed transfer unit; and a cooling unit configured to dissipate heat generated from the light projection unit.

### CROSS-REFERENCE TO RELATED APPLICATION

This application claims priority to and the benefit of Korean Patent Application No. 2018-0001066, filed on Jan. 4, 2018, the disclosure of which is incorporated herein by reference in its entirety.

### BACKGROUND OF THE INVENTION

### 1. Field of the Invention

The present disclosure relates to a three-dimensional (“3D”) printer using a linear laser light source that shapes a three-dimensional object by projecting laser light to a photocurable liquid resin and, more particularly, to a 3D printer having a cooling function for cooling a linear laser light source.

### 2. Description of the Prior Art

Generally, in order to produce a prototype having a 3D shape, a mockup manufacturing method and a CNC milling-based manufacturing method and the like are widely known.

However, the mockup manufacturing method is manually performed, and thus it is difficult to perform precise numerical control and it takes a lot of time to perform the method. Although the CNC milling-based manufacturing method is capable of performing precise numerical control, there are many products difficult to process using the CNC milling-based manufacturing method due to tool interference.

In recent years, a so-called 3D printing method has appeared in which a product designer creates 3D modeling data using CAD or CAM, and a prototype having a 3D shape using the generated data is manufactured. Such a 3D printing method is used in various fields such as industry, life, and medical science.

A 3D printer is an apparatus for manufacturing an object by outputting successive layers of a material like a 2D printer and stacking the successive layers. Such a 3D printer is capable of manufacturing an object quickly based on digitized drawing information and is mainly used for manufacturing a prototype sample or the like.

Product molding methods using a 3D printer include a photocurable resin shaping method using a Stereo Lithography Apparatus (SLA), in which a photocurable material is scanned using laser light so as to shape the portion scanned by the laser light into an object, or a Selective Laser Melting Method (SLM), in which a thermoplastic filament is melted and stacked.

In the molding methods using a 3D printer, a photocurable-resin-shaping-type 3D printer is configured to mold a 3D object by projecting laser light to a tank in which the photocurable liquid resin is stored so as to cure the liquid resin.

Here, a light projection device for projecting laser light is configured such that a galvanometer mirror is installed between a laser light source and a bed in which a 3D object is molded and this 3D object is molded while performing X-Y axis control of the galvanometer mirror and simultaneously performing Z-axis control of the bed.

However, in such a conventional 3D printer, the size of the light projection device is increased due to the structure of the galvanometer mirror subjected to the X-Y axis control, and the configuration of the controller becomes complicated due to the control of the galvanometer mirror and the bed.

Further, a large amount of heat is generated from the laser light projection device, and thus a device for cooling the laser light projection device without greatly increasing its overall size is demanded.

### SUMMARY OF THE INVENTION

The present disclosure has been made in order to solve the problems described above, and an aspect of the present disclosure is to provide a 3D printer having a cooling function capable of minimizing the size of the device and removing heat generated from a light source.

In accordance with the aspects described above, the present disclosure provides a 3D printer having a cooling function. The 3D printer includes: a tank configured to store therein a photocurable liquid resin; a bed configured to be moveable in a vertical direction within the tank and to support a shaping object; a bed transfer unit configured to move the bed in the vertical direction; a light projection unit configured to linearly project laser light to the photocurable liquid resin stored in the tank in a longitudinal direction of the tank so as to cure the photocurable liquid resin into the shaping object; a light projection unit transfer unit configured to move the light projection unit in a width direction of the tank; a control unit configured to control operations of the light projection unit, the light projection unit transfer unit, and the bed transfer unit; and a cooling unit installed on one side of the light projection unit and configured to dissipate heat generated from the light projection unit.

The light projection unit may include: a light projection unit main body fixed to the light projection unit transfer unit so as to be transferred in the width direction of the tank; a laser diode embedded in the light projection unit main body and configured to project laser light in one direction; a polygon mirror embedded in the light projection unit main body and configured to linearly reflect the laser light projected from the laser diode in the longitudinal direction of the tank while rotating; and a refraction mirror installed within the light projection unit main body and configured to refract the laser light reflected from the polygon mirror to the photocurable liquid resin within the tank.

In addition, the light projection unit may further include: a cylindrical lens configured to condense the laser light projected from the laser diode on a reflection surface of the polygon mirror; a first F-θ Lens installed between the polygon mirror and the refraction mirror and configured to condense the laser light reflected from a reflection surface of the polygon mirror toward the tank; and a second F-θ Lens installed between the first F-θ lens and the refraction mirror and configured to condense the laser light reflected from a reflection surface of the polygon mirror toward the tank.

The polygon mirror may include a rotation shaft disposed perpendicular to a surface of the liquid resin within the tank so as to have a rotation plane parallel to the surface of the liquid resin

The light projection unit may further include: a beam-detecting sensor configured to receive the laser light reflected from the polygon mirror so as to determine an output start position of image data of the shaping object; and a beam-detecting mirror configured to reflect the laser light reflected from the polygon mirror to the beam-detecting sensor.

A plurality of laser diodes may be provided so as to be spaced apart from each other at a predetermined interval in a circumferential direction around one point of the polygon mirror, and the plurality of laser diodes may project laser light such that the laser light is superimposed on the one point of the polygon mirror.

The cooling unit may include a heat dissipation fan provided on a plate on one side of the light projection unit main body and a Peltier thermoelectric element provided between the plate and the heat dissipation fan and configured to absorb heat from the plate and to discharge heat through the heat dissipation fan.

Here, the cooling unit may further include a heat sink installed between the Peltier thermoelectric element and the heat dissipation fan, and the heat sink may be fixed onto the plate by a bolt made of a plastic material, and the plate may be made of a metal material.

A 3D printer having a cooling function according to the present disclosure has a structure in which the laser beam projected from the light projection unit moves in the horizontal direction while being formed linearly. Thus, it is possible to simplify the structure of the apparatus, compared with the conventional type in which X-Y axis control is performed on the galvanometer mirror, whereby it is possible to reduce the projecting time of laser light and thus to reduce the shaping time of a 3D object.

According to the present disclosure, a cooling unit is provided on one side of the light projection unit main body. Thus, heat generated from the light projection unit can be dissipated effectively.

### BRIEF DESCRIPTION OF THE DRAWINGS

The above and other aspects, features, and advantages of the present disclosure will be more apparent from the following detailed description taken in conjunction with the accompanying drawings, in which:

FIG. 1 is a perspective view illustrating a 3D printer having a cooling function according to the present disclosure;

FIG. 2 is a perspective view of the 3D printer having a cooling function according to the present disclosure, which is viewed in another direction;

FIG. 3 is a front view illustrating the 3D printer having a cooling function according to the present disclosure;

FIG. 4 is a side view illustrating the 3D printer having a cooling function according to the present disclosure;

FIG. 5 is a perspective view illustrating a bed and a bed transfer unit of the 3D printer having a cooling function according to the present disclosure;

FIG. 6 is a perspective view illustrating a light projection unit transfer unit of the 3D printer having a cooling function according to the present disclosure;

FIG. 7 is a perspective view illustrating a light projection unit of the 3D printer having a cooling function according to the present disclosure;

FIG. 8 is a perspective view illustrating the inside of a light projection unit of the 3D printer having a cooling function according to the present disclosure; and

FIG. 9 is a perspective view illustrating a cooling device of a light projection unit of the 3D printer having a cooling function according to the present disclosure.

### DETAILED DESCRIPTION OF THE EXEMPLARY EMBODIMENTS

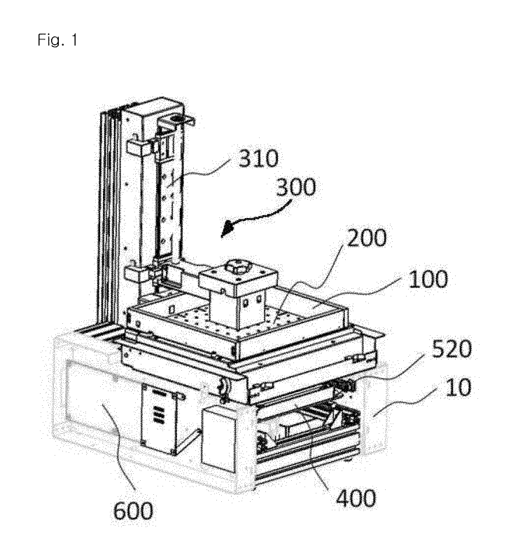

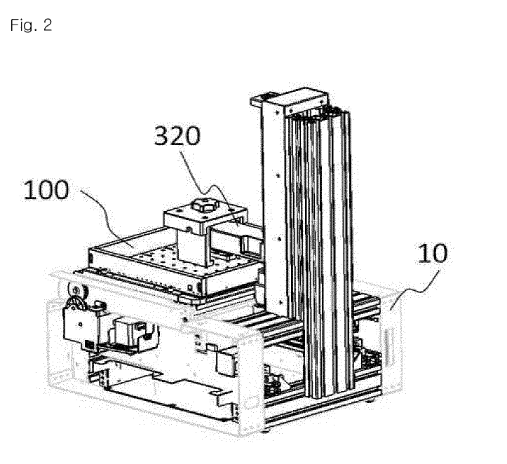

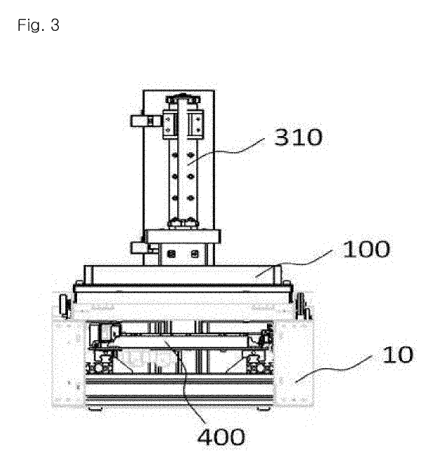

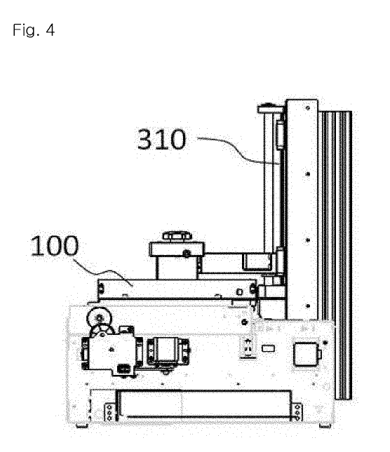

Referring to FIGS. 1 to 4, a 3D printer having a cooling function according to the present disclosure includes a tank 100 configured to store a photocurable liquid resin therein, a bed 200 configured to support a molded object thereon within the tank 100, a bed transfer unit 300 configured to transfer the bed 200, a light projection unit 400 configured to project laser light to the photocurable liquid resin so as to cure the photocurable liquid resin into a shaping object, a light projection unit transfer unit 500 configured to move the light projection unit 400, and a control unit 600 configured to control the operation of the light projection unit 400, the light projection unit transfer unit 500, and the bed transfer unit 300.

The tank 100 is installed on the upper portion of a main body frame 10, and stores a photocurable liquid resin therein.

The bed 200 serves to support a molded object, i.e., a 3D object, which is produced by curing the photocurable liquid resin by laser light. The bed 200 is configured to be movable in a vertical direction within the tank 100 by the bed transfer unit 300.

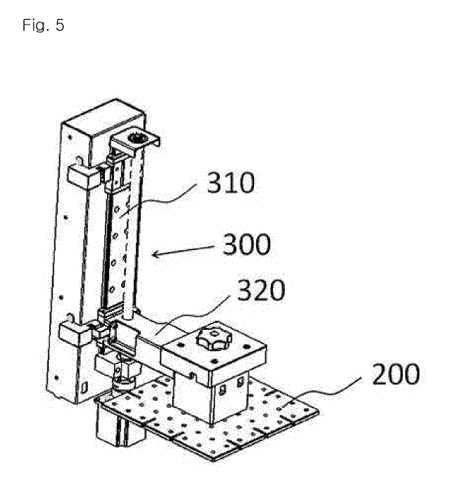

The bed transfer unit 300 includes a vertical transfer rail 310 and a transfer member 320 movable in the vertical direction along the vertical transfer rail 310. The vertical transfer rail 310 is vertically installed on one side surface of the main body frame 10. One end of the transfer member 320 is configured to be vertically movable along the vertical transfer rail 310 and the other end of the transfer member 320 is engaged with the bed 200 so as to move the bed 200 in the vertical direction (see FIG. 5).

The light projection unit 400 projects laser light according to a pattern set in the photocurable liquid resin stored in the tank 100 so as to cure the photocurable liquid resin into a three-dimensional molded object. Here, the light projection unit 400 is configured to project the laser light linearly in a longitudinal direction of the tank 100 and to be movable in a width direction of the tank 100 by the light projection unit transfer unit 500.

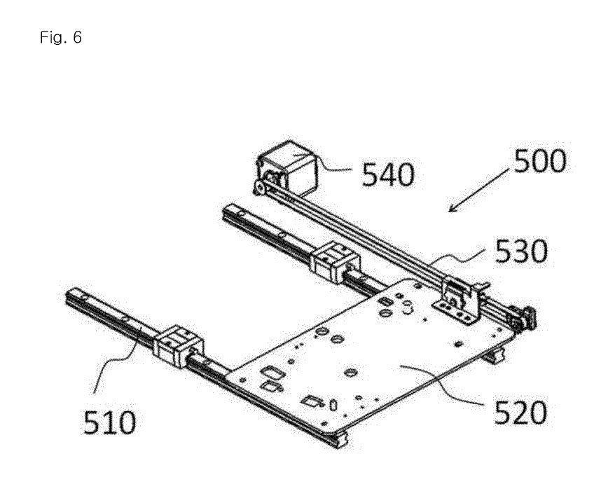

The light projection unit transfer unit 500 includes horizontal transfer rails 510 and a moving plate 520 movable in a horizontal direction, i.e. in the width direction of the tank 100 along the horizontal transfer rail 510. The horizontal transfer rails 510 are horizontally installed along the left and right surfaces of the main body frame 10. The moving plate 520 is installed between a pair of horizontal moving rails 510 and moves along the horizontal moving rails 510 by a gear motor 540 connected to a driving belt 530. In addition, a light projection unit 400 is fixed on the upper surface of the moving plate 520 (see FIG. 6).

The control unit 600 is installed on the left surface of the body frame 10 and controls the operations of the light projection unit 400, the light projection unit transfer unit 500, and the bed transfer unit 300 on the basis of data concerning an inputted molded object such that the inputted molded object is generated.

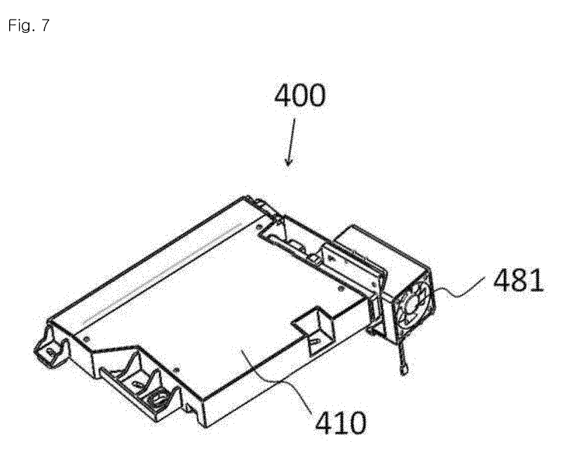

Referring to FIGS. 7 to 9, the light projection unit 400 includes a light projection unit main body 410 having a predetermined space therein, a laser diode 420 installed inside the light projection unit main body 410, a polygon mirror 430, and a refraction mirror 440.

The light projection unit main body 410 is fixed on a moving plate 520 of the light projection unit transfer unit 500 and moves in the width direction of the tank 100 together with the moving plate 520.

The laser diode 420 is embedded in the light projection unit main body 410 and projects laser light in a direction in which the polygon mirror 430 is installed. Here, the laser diode 420 projects ultraviolet light having a wavelength of about 350 to 420 nm and an output of about 600 to 1000 mW.

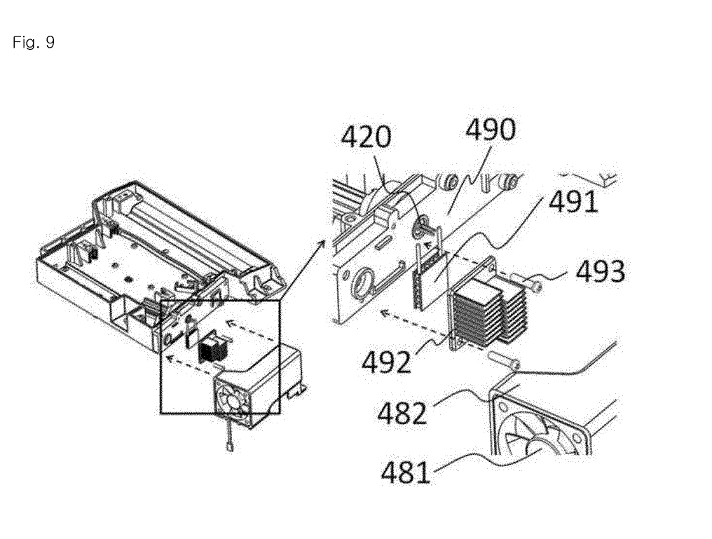

The polygon mirror 430 is embedded in the light projection unit main body 410 and reflects the laser light projected from the laser diode 420 while being rotated by a motor 431. Here, the polygon mirror 430 includes six reflection surfaces, and the motor 431 rotates the polygon mirror 430 at a speed of 20,000 to 43,000 rpm. Here, the polygon mirror 430 is installed in the light projection unit main body 410 such that the rotation axis of the polygon mirror 430 is perpendicular to the surface of the liquid resin filled in the tank 100. Therefore, the rotation plane of the polygon mirror 430 is disposed parallel to the surface of the liquid resin. The laser light reflected from the polygon mirror 430 is linearly reflected in the longitudinal direction of the tank 100 as illustrated in FIG. 9 by the rotation of the polygon mirror 430.

Meanwhile, a plurality of laser diodes 420 may be provided and spaced apart from each other at a predetermined interval in a circumferential direction around one point R of a reflection surface of the polygon mirror 430. The laser diodes 420 project laser light such that the laser light is superimposed on one point on a reflection surface of the polygon mirror 430, and thus the output of the laser light projected to the photocurable resin in the tank 100 through a reflection surface increases such that the photo-curing shaping speed is increased in proportion to the output of the laser light.

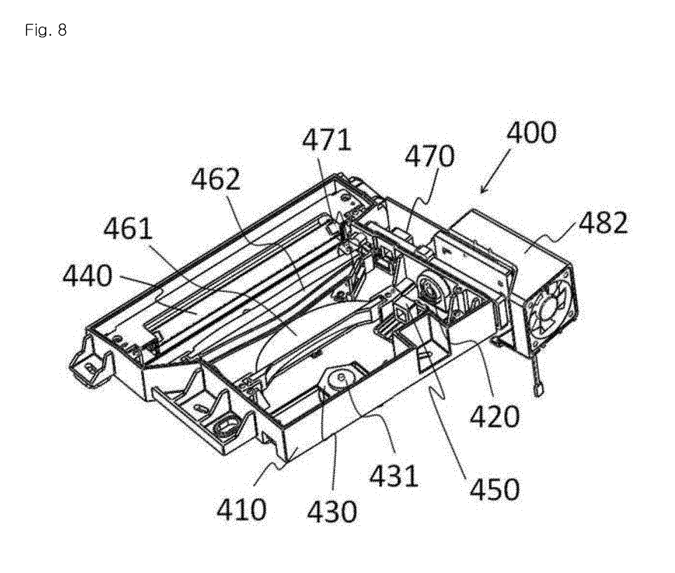

As illustrated in FIG. 8, the refraction mirror 440 is provided inside the light projection unit 400 and serves to refract the laser light reflected from the polygon mirror 430 toward the photocurable liquid resin inside the tank 100.

With this configuration, high-output and short-wavelength laser light projected from the laser diode 420 is reflected by the polygon mirror 430 to form a linear laser beam L in the longitudinal direction of the tank 100, and the laser light can be projected onto a 2D plane while horizontally moving the light projection unit 400. In addition, a 3D shaping object can be shaped by projecting laser beam to the 3D shaping object while vertically moving the bed 200.

Here, the photocurable-resin-shaping-type 3D printer according to the present disclosure is configured such that the laser light projected from the light projection unit 400 is reflected from the polygon mirror 430 having a rotating plane which is parallel to the surface of the liquid resin stored in the tank 100 and moves in the horizontal direction while forming a linear laser beam Thus, it is possible to simplify the structure of the apparatus, compared with the conventional type in which X-Y axis control is performed on the galvanometer mirror, it is possible to improve the rotation quality and life of the polygon mirror, compared with the conventional type using a polygon mirror having a rotation plane disposed in an inclined or perpendicular direction with respect to the surface of the liquid resin, and it is possible to reduce the projecting time of laser light and thus to reduce the shaping time of a 3D object. In addition, it is possible to implement a control unit 600 with a simple configuration since only the light projection unit transfer unit 500 and the bed transfer unit 300 are controlled.

Preferably, the light projection unit 400 may include lenses 450, 461, and 462 (e.g., a cylindrical lens 450, a first F-θ lens 461, and a second F-θ lens 462) so as to condense the laser beam projected from the laser diode 420.

The cylindrical lens 450 is installed between the laser diode 420 and the polygon mirror 430 and condenses the laser light on a reflection surface of the polygon mirror 430 in the vertical direction. The first F-θ lens 461 is installed between the polygon mirror 430 and the refraction mirror 440 and condenses the laser light reflected from a reflection surface of the polygon mirror 430 toward the tank. The second F-θ lens 462 is installed between the first F-θ lens 461 and the refraction mirror 440 and condenses the laser light reflected from a reflection surface of the polygon mirror 430 toward the tank. Here, the first F-θ lens 461 and the second F-θ lens 462 are constituted by one set of two lenses, and thus the condensed laser light has a size of Ø0.05 to Ø0.1 mm.

The light projection unit 400 may further include a beam-detecting sensor 470 and a beam-detecting mirror 471 such that the control unit 600 is capable of determining an output start position of image data of a shaping object.

The beam detecting sensor 470 receives laser the light reflected from the polygon mirror 430 and transmits light-receiving information to the control unit 600. The beam detecting mirror 471 reflects the laser light reflected from the polygon mirror 430 toward the beam-detecting sensor 470. Then, the control unit 600 determines the output start position of the image data of the shaping object on the basis of the light-receiving information received from the beam-detecting sensor 470. That is, the control unit 600 serves to synchronize the resists of respective shaping layers.

Meanwhile, since the laser diode 420, which is a light source of the light projection unit, generates heat due to the high output thereof, the performance thereof cannot be maintained unless cooling and heat dissipation are not performed thereon properly. For this reason, the 3D printer having a cooling function according to the present disclosure has a configuration for the cooling function.

Specifically, the laser diode 420 is press-fitted to a plate 490 on one side of the light projection unit main body 410 in order to dissipate heat generated from the light projection unit 400. Thus, it is necessary for the plate 490 to be made of a metal material, rather than a plastic material. The plate 490 on the one side of the light projection unit main body 410 is provided with a heat dissipation fan 482 in order to cool the laser diode 420. Here, it has been confirmed that an air-cooling method using the heat dissipation fan 482 has no significant problem in a room-temperature environment. However, in a high-temperature environment of about 28 to 30° C., it is impossible to achieve sufficient cooling only with the heat dissipation fan 482. In order to compensate for the cooling effect of the heat dissipation fan 482, the 3D printer having a cooling function according to the present disclosure may further include a Peltier thermoelectric element 491 installed between the plate 490 of the light projection unit main body 410 and the heat dissipation fan 482. The Peltier thermoelectric element 491 is attached to the plate 490 and is capable of absorbing heat transmitted to the plate 490 through an endothermic reaction. In addition, a heat sink 492 is provided on the other side of the Peltier thermoelectric element 491, that is, between the Peltier thermoelectric element 491 and the heat dissipation fan 482. Accordingly, one side surface of the Peltier thermoelectric element 491 is attached to the plate 490 so as to absorb heat and the other side surface of the Peltier thermoelectric element 491 is brought into close contact with the heat sink 492 to discharge the heat dissipated from the plate 490. At this time, the heat of the heat sink 492 may be discharged to the outside through the heat dissipation fan 482.

Meanwhile, the heat sink 492 is fixed to the plate 490 through bolts 493, which may be made of a plastic material rather than a metal for effective heat dissipation. In fact, when the bolts 493 are made of a metal material, the heat from the heat sink 492 may be transferred to the plate 490 side, which results in a reduction in heat dissipation effect. However, when the bolts 493 are made of a plastic material, it is possible to block the heat from the heat sink 492 from being transferred to the plate 490 side, and thus it is possible to improve the cooling performance by about 2° C.

What is claimed is:

1. A 3D printer having a cooling function, the 3D printer comprising:
a tank configured to store therein a photocurable liquid resin;
a bed configured to be moveable in a vertical direction within the tank and to support a shaping object;
a bed transfer unit configured to move the bed in the vertical direction;
a light projection unit configured to linearly project laser light to the photocurable liquid resin stored in the tank in a longitudinal direction of the tank so as to cure the photocurable liquid resin into the shaping object;
a light projection unit transfer unit configured to move the light projection unit in a width direction of the tank;
a control unit configured to control operations of the light projection unit, the light projection unit transfer unit, and the bed transfer unit; and
a cooling unit installed on one side of the light projection unit and configured to dissipate heat generated from the light projection unit.

2. The 3D printer of claim 1, wherein the light projection unit comprises:
a light projection unit main body fixed to the light projection unit transfer unit so as to be transferred in the width direction of the tank;
a laser diode embedded in the light projection unit main body and configured to project laser light in one direction;
a polygon mirror embedded in the light projection unit main body and configured to linearly reflect the laser light projected from the laser diode in the longitudinal direction of the tank while rotating; and
a refraction mirror installed within the light projection unit main body and configured to refract the laser light reflected from the polygon mirror to the photocurable liquid resin within the tank.

3. The 3D printer of claim 2, wherein the light projection unit further comprises:
a cylindrical lens configured to condense the laser light projected from the laser diode on a reflection surface of the polygon mirror;
a first F-θ Lens installed between the polygon mirror and the refraction mirror and configured to condense the laser light reflected from a reflection surface of the polygon mirror toward the tank; and
a second F-θ Lens installed between the first F-θ lens and the refraction mirror and configured to condense the laser light reflected from a reflection surface of the polygon mirror toward the tank.

4. The 3D printer of claim 2, wherein the polygon mirror comprises a rotation shaft disposed perpendicular to a surface of the liquid resin within the tank so as to have a rotation plane parallel to the surface of the liquid resin

5. The 3D printer of claim 2, wherein the light projection unit further comprises:
a beam-detecting sensor configured to receive the laser light reflected from the polygon mirror so as to determine an output start position of image data of the shaping object; and
a beam-detecting mirror configured to reflect the laser light reflected from the polygon mirror to the beam-detecting sensor.

6. The 3D printer of claim 2, wherein a plurality of laser diodes are provided so as to be spaced apart from each other at a predetermined interval in a circumferential direction around one point of the polygon mirror, and the plurality of laser diodes projects laser light such that the laser light is superimposed on the one point of the polygon mirror.

7. The 3D printer of claim 2, wherein the cooling unit comprises a heat dissipation fan provided on a plate on one side of the light projection unit main body and a Peltier thermoelectric element provided between the plate and the heat dissipation fan and configured to absorb heat from the plate and to discharge heat through the heat dissipation fan.

8. The 3D printer of claim 7, wherein the cooling unit further comprises a heat sink installed between the Peltier thermoelectric element and the heat dissipation fan, and the heat sink is fixed onto the plate by a bolt made of a plastic material, and the plate is made of a metal material.
